(19) United States
(12) Patent Application Publication
(10) Pub. No.: US 2010/0272887 A1
(43) Pub. Date: Oct. 28, 2010

(54) THIN FILM FORMING APPARATUS AND THIN FILM FORMING METHOD

(76) Inventors: Kazuyoshi Honda, Osaka (JP); Yuma Kamiyama, Kyoto (JP); Tomofumi Yanagi, Osaka (JP); Yasuharu Shinokawa, Osaka (JP); Masahiro Yamamoto, Osaka (JP)

Correspondence Address: MCDERMOTT WILL & EMERY LLP, 600 13TH STREET, NW, WASHINGTON, DC, 20005-3096, US

(21) Appl. No.: 12/738,951

(22) PCT Filed: Nov. 5, 2008
(86) PCT No.: PCT/JP2008/003185

§ 371 Date: Apr. 20, 2010

(30) Foreign Application Priority Data
Nov. 6, 2007 (JP) 2007-288347
Dec. 17, 2007 (JP) 2007-324339

(51) Int. Cl. B05D 3/12; C23C 14/00; B05D 3/00

(52) U.S. Cl. 427/171; 118/50; 427/294

(57) ABSTRACT

To provide a thin film forming apparatus capable of uniformly and adequately cooling down a substrate. The thin film forming apparatus of the present invention forms a thin film on an elongated substrate in vacuum and includes: a cooling body 1 provided close to a rear surface of the substrate being transferred at an opening 31; a gas introducing unit configured to introduce a gas to between the cooling body 1 and the substrate 21; and a substrate holding unit 3 configured to hold vicinities of both width-direction ends of the substrate traveling at the opening 31.

### TECHNICAL FIELD

The present invention relates to a thin film forming apparatus and a thin film forming method.

### BACKGROUND ART

A thin film technology is widely used to enhance device performances and reduce device sizes. Realizing thin-film devices brings direct merits to users, and in addition, plays an important role from an environmental point of view, such as protection of earth resources and a reduction in power consumption.

For the development of the thin film technology, it is essential to respond to demands from industrial use, such as increases in efficiency, stability, and productivity of the thin film manufacturing method and a reduction in cost of the thin film manufacturing method. Therefore, efforts to respond to those demands are being continued.

In order to realize the increase in productivity of the thin film, a high-deposition-rate film forming technology is essential. In the thin film manufacture, such as vacuum deposition, sputtering, ion plating, and CVD, an increase in deposition rate is being promoted. Used as a method for continuously mass-producing the thin film is a take-up type thin film manufacturing method. The take-up type thin film manufacturing method is a method for pulling out an elongated substrate, rolled in a roll shape, from a pull-out roll, forming the thin film on the substrate while the substrate is transferred along a transfer system, and taking up the substrate by a take-up roll. By combining the take-up type thin film manufacturing method with a high-deposition-rate film forming source, such as a vacuum deposition source using an electron beam, the thin film can be formed with high productivity.

One factor determining success and failure of such continuous take-up type thin film manufacturing is a problem of a heat load during film formation. For example, in the case of the vacuum deposition, heat radiation from the evaporation source and heat energy of evaporated atoms are applied to the substrate to increase the temperature of the substrate. Especially in a case where the temperature of the evaporation source is increased or the evaporation source and the substrate are provided close to each other to increase the deposition rate, the temperature of the substrate increases excessively. If the temperature of the substrate becomes too high, the mechanical characteristic of the substrate significantly deteriorates. This may cause problems, such as a large deformation of the substrate by heat expansion of the deposited thin film and meltdown of the substrate. In the other film forming methods, although the heat source is different, the heat load is applied to the substrate during the film formation, and this causes the same problems.

In order to prevent the substrate from, for example, deforming or melting down, the substrate is cooled down during the film formation. An operation of forming the film with the substrate provided along a cylindrical can disposed on a passage of the transfer system is widely carried out to cool down the substrate. By securing thermal contact between the substrate and the cylindrical can by this method, the heat can be transferred to the cooling can having a high heat capacity. Therefore, the temperature of the substrate can be prevented from increasing, and the temperature of the substrate can be kept at a specific cooling temperature.

One of methods for securing the thermal contact between the substrate and the cylindrical can in a vacuum atmosphere is a gas cooling method. The gas cooling method is a method for cooling down the substrate such that: a small gap of several millimeters or less is kept between the substrate and the cylindrical can that is a cooling body; a minute amount of gas is supplied to the gap; and the thermal contact between the substrate and the cylindrical can is secured by utilizing gas heat conduction. Document 1 describes that in an apparatus configured to form the thin film on a web that is the substrate, the gas is supplied to a region between the web and the cylindrical can that is a supporting unit. In accordance with this, since the thermal conduction between the web and the supporting unit can be secured, the increase in temperature of the web can be suppressed.

As a means for cooling the substrate, a cooling belt can also be used instead of the cylindrical can. In the case of forming the film by oblique incidence, forming the film with the substrate moving linearly is advantageous from a viewpoint of the use efficiency of a material. In this case, it is effective to use the cooling belt as the substrate cooling unit. Document 2 discloses a method for cooling down a belt in a case where the belt is used to transfer and cool down the material of the substrate. In accordance with Document 2, in order to further cool down a cooling band, a cooling mechanism using a double or more cooling bands or a liquid medium is provided inside the cooling body. With this, the cooling efficiency can be increased. Therefore, an electromagnetic tape characteristic, such as an electromagnetic conversion characteristic, can be improved, and the productivity can also be improved significantly.

Document 1: Japanese Laid-Open Patent Application Publication No. 1-152262

Document 2: Japanese Laid-Open Patent Application Publication No. 6-145982

### DISCLOSURE OF THE INVENTION

### Problems to be Solved by the Invention

In the case of carrying out the gas cooling described in Document 1, it is desirable that in order to increase the heat conductivity, an interval between the substrate and the cooling body be as small as possible and be uniform. However, by supplying the cooling gas, the pressure increases locally between the substrate and the cooling body, and the thermal stress is generated on the substrate by the heat from the evaporation source. With this, the substrate expands like a balloon to bend. On this account, a gap between the substrate and the cooling body becomes large at the vicinity of a width-direction center portion of the substrate, and the interval between the cooling body and the substrate becomes nonuniform. Therefore, it is difficult to uniformly and adequately carry out the cooling. In order to improve the performance of the gas cooling, it is effective to increase the pressure between the substrate and the cooling body. However, if the amount of gas introduction is increased to increase the pressure, the above bending becomes further significant. On this account, it is especially difficult to enhance the cooling at the vicinity of the width-direction center portion of the substrate.

In the case of forming the film by the oblique incidence, forming the film using the cooling belt described in Document 2 with the substrate moving linearly is advantageous from a viewpoint of the use efficiency of the material. However, in the film formation using the cooling belt, in a case where the heat load with respect to the substrate is high due to, for example, especially a high film formation rate, it is difficult to adequately cool down the substrate. This is because in a case where the substrate moves linearly, a normal-direction power of the substrate cannot be obtained, and a power toward the cooling body cannot be secured. In a case where the power toward the cooling body is not secured, the thermal contact between the substrate and the cooling belt cannot be secured adequately.

For example, once the substrate deforms by the high heat load, a heat transfer performance between the substrate and the cooling body deteriorates. Therefore, the cooling performance deteriorates, and the substrate further deforms.

The present invention was made to solve the above problems, and an object of the present invention is to provide a thin film forming apparatus and a thin film forming method, each of which is capable of uniformly and adequately cooling down the substrate in order to prevent the deformation and meltdown of the substrate due to the heat load during the film formation when continuously forming the thin film on the surface of the substrate while transferring the substrate.

### Means for Solving the Problems

In order to solve the above problems, a thin film forming apparatus of the present invention is a thin film forming apparatus configured to form a thin film on an elongated substrate in vacuum and includes: a transfer mechanism configured to transfer the substrate; a thin film forming unit including a film forming source for forming the thin film on a front surface of the substrate in a thin film forming region while the substrate is being transferred; a cooling body provided close to a rear surface of the substrate being transferred in the thin film forming region; a gas introducing unit configured to introduce a gas to between the cooling body and the substrate; a substrate holding unit configured to hold vicinities of both width-direction ends of the substrate in the thin film forming region while causing the substrate to travel; and a vacuum container configured to store the transfer mechanism, the thin film forming unit, the cooling body, the gas introducing unit, and the substrate holding unit.

The substrate holding unit is not especially limited as long as it can prevent the substrate from bending in the width direction of the substrate due to gas introduction and heat from an evaporation source such that the substrate holding unit holds, while causing the substrate to travel, both width-direction end portions of the substrate adjacent to the thin film forming region where the thin film is formed on the surface of the substrate being transferred. Specifically, the substrate holding unit is a width-direction tension applying unit configured to apply tension to the substrate in a width direction of the substrate in the thin film forming region while causing the substrate to travel or an endless band configured to adsorb to the rear surface of the substrate in a part of the thin film forming region when viewed in a substrate width direction and travel together with the substrate.

Moreover, a thin film forming method of the present invention is a thin film forming method for forming a thin film on a surface of an elongated substrate in vacuum and includes the step of: providing a cooling body close to a rear surface of the substrate being transferred in a thin film forming region; and forming the thin film on a front surface of the substrate while introducing a gas to between the cooling body and the substrate to cool down the substrate and while holding, in the thin film forming region, vicinities of both width-direction ends of the substrate being traveled.

### Effects of the Invention

In accordance with the thin film forming apparatus and the thin film forming method of the present invention, although the substrate intends to bend by the introduction of the cooling gas, this bending is prevented by holding both width-direction end portions of the substrate. Therefore, even in a case where the amount of gas introduction is increased and the pressure between the substrate and the cooling body is increased to improve the performance of the gas cooling, the interval between the substrate and the cooling body can be made small and uniform. On this account, the substrate can be uniformly and adequately cooled down. With this, it is possible to realize the thin film formation at high film forming rate while preventing the substrate from deforming and melting down due to the heat load during the film formation.

### BRIEF DESCRIPTION OF THE DRAWINGS

FIG. 1 are schematic structural diagrams showing one example of a substrate cooling mechanism that is a part of each of Embodiments 1 and 4 of the present invention. FIG. 1(a) is a cross-sectional view, and FIG. 1(b) is a front view.

FIG. 2 are schematic structural diagrams showing one example of the substrate cooling mechanism that is a part of Embodiment 2 of the present invention. FIG. 2(a) is a cross-sectional view, and FIG. 2(b) is a front view.

FIG. 3 are schematic structural diagrams showing one example of the substrate cooling mechanism that is a part of Embodiment 3 of the present invention. FIG. 3(a) is a cross-sectional view, FIG. 3(b) is a front view, and FIG. 3(c) is a partially enlarged view of a rotary sliding body.

FIG. 4 is a schematic diagram showing one example of the configuration of an entire film forming apparatus.

FIG. 5 is a schematic diagram showing one example of a method for introducing a gas to between a cooling body and the substrate.

FIG. 6 are schematic diagrams showing one example of the method for introducing the gas to between the cooling body and the substrate. FIG. 6(a) is a cross-sectional view, and FIG. 6(b) is a partially enlarged view of a gas nozzle 34.

FIG. 7 is a schematic diagram showing one example of a method for introducing the gas to between the cooling body and the substrate and suctioning a part of an accumulated gas.

FIG. 8 is a schematic structural diagram showing one example of the substrate cooling mechanism that is a part of Embodiment 1 of the present invention.

FIG. 9 are schematic structural diagrams showing one example of a clip mechanism that is a part of Embodiment of the present invention. FIG. 9(a) is a diagram of a spring type, FIG. 9(b) is a diagram of a pneumatic type, and FIG. 9(c) is a diagram of an electrostatic type.

FIG. 10 is a schematic diagram showing positions of an endless band and a cooling body in the film forming apparatus in Embodiment 4 of the present invention.

FIG. 11 is a schematic diagram showing the position of a shielding plate in Embodiment 4 of the present invention.

FIG. 12 is a diagram showing one example of the configuration of the endless band in Embodiment 4 of the present invention.

FIG. 13 is a schematic diagram showing the configuration of the film forming apparatus in Embodiment 5 of the present invention.

FIG. 14 is a schematic diagram showing one example of the substrate cooling mechanism in Embodiment 5 of the present invention.

### EXPLANATION OF REFERENCE NUMBERS

1 cooling body

2 support roller

3 endless body

4 angle formed by a traveling direction of a substrate and a traveling direction of an endless body contacting the substrate

5 clip mechanism

6 clip transfer system

7 clip piece

8 compression spring

9 pneumatic cylinder

10 release spring

11 dielectric layer

12 rotary sliding body

12a rotational direction of the rotary sliding body

12b tangential movement direction of the rotary sliding body at a position where the rotary sliding body contacts the substrate

13 release body

14 angle formed by a substrate traveling direction 38 and the tangential movement direction 12b of the rotary sliding body at the position where the rotary sliding body contacts the substrate

15 electron gun

17 rotation source

18 electron beam

19 evaporation crucible

20 film forming apparatus

21 substrate

22 vacuum chamber

23 pull-out roller

24 feed roller

26 take-up roller

27 film forming source

29 shielding plate

30 material gas introducing tube

31 opening

32 manifold

33 fine hole

34 gas nozzle

35 cooling gas introducing port

36 exhaust port

37 exhaust unit

38 substrate traveling direction

41 shielding plate

43 insulating layer

44 electrically-conductive layer

45 base material

49 cooling can

### BEST MODE FOR CARRYING OUT THE INVENTION

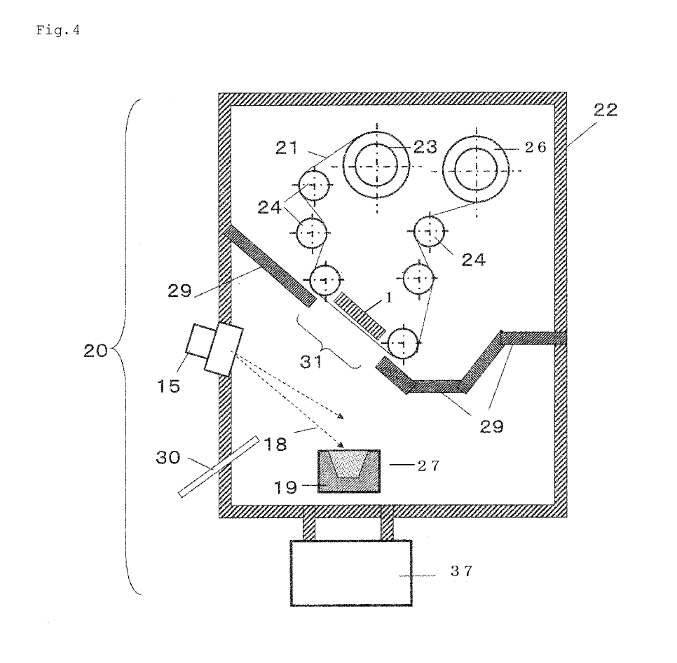

One example of the configuration of an entire film forming apparatus in a case where a substrate is linearly transferred in a thin film forming region is schematically shown in FIG. 4. A vacuum chamber 22 is a pressure-resistant container-like member having an internal space. A pull-out roller 23, a plurality of feed rollers 24, an opening 31 that is the thin film forming region, a take-up roller 26, a film forming source 27, a shielding plate 29, and a material gas introducing tube 30 are stored in the internal space. The pull-out roller 23 is a roller-like member provided to be rotatable around a center axis thereof. A band-shaped elongated substrate 21 winds around the surface of the pull-out roller 23. The pull-out roller 23 supplies the substrate 21 to the closest feed roller 24.

Each of the feed rollers 24 is a roller-like member provided to be rotatable around a center axis thereof. The feed rollers 24 guide the substrate 21, supplied from the pull-out roller 23, to the opening 31 and finally guides the substrate 21 to the take-up roller 26. When the substrate 21 travels along the opening 31, material particles flying from the film forming source reacts with a material gas introduced from the material gas introducing tube 30 according to need to be deposited on the substrate 21. Thus, a thin film is formed on the surface of the substrate 21. The take-up roller 26 is a roller-like member provided to be rotatable by a driving unit, not shown. The take-up roller 26 takes up and stores the substrate 21 on which the thin film is formed.

Various film forming sources can be used as the film forming source 27. Examples are evaporation sources using resistance heating, induction heating, and electron beam heating, ion plating sources, sputtering sources, and CVD sources. In addition, as the film forming source, a combination of an ion source and a plasma source can be used. For example, the film forming source includes a container-like member and a film forming material. The container-like member is provided under a lowermost portion of the opening 31 in a vertical direction, and a vertically upper portion thereof is open. The film forming material is mounted inside the container-like member. One specific example of the container-like member is an evaporation crucible 19. A heating unit, such as an electron gun 15, is provided in the vicinity of the film forming source 27. The film forming material in the evaporation crucible 19 is heated and evaporates by, for example, an electron beam 18 emitted from the electron gun. The vapor of the material moves upward in the vertical direction through the opening 31 to adhere to the surface of the substrate 21. Thus, the thin film is formed. The film forming source 27 applies a heat load to the substrate.

The shielding plate 29 limit a region where the material particles flying from the evaporation crucible 19 contact the substrate 21 to only the opening 31.

On a rear surface side of the substrate located in the vicinity of the opening 31, a cooling body 1 is provided close to the substrate. A gap is provided between the rear surface of the substrate and the cooling body 1, and the interval of the gap is set to, for example, 2 mm or less. The interval of the gap significantly affects the cooling performance. Narrower the interval is, higher the cooling performance becomes. However, if the interval is too narrow, the substrate and the cooling body may contact depending on a positional accuracy at the time of the transfer of the substrate, and the substrate may be damaged and deteriorate its product features. Therefore, practically, it is preferable that the interval be set to a range from 0.3 to 1.0 mm.

Further, a gas is introduced to between the cooling body 1 and the rear surface of the substrate. At this time, by preventing the substrate from bending by the introduction of the gas, the interval between the substrate 21 and the cooling body 1 is maintained small and uniform, and the substrate is stably cooled down.

A material of the cooling body 1 is not especially limited. Examples are metals, such as copper, aluminum, and stainless steel, which can secure a worked shape, carbons, various ceramics, and engineering plastics. Especially, it is more preferable to use the metal, such as copper or aluminum, having high heat conductivity, since such metal is unlikely to generate dust and excels in the heat resistance, and the temperature of such metal is easily uniformized.

The cooling body 1 is cooled down by a cooling medium. The cooling medium is normally a liquid or a gas, and typically water. A cooling medium passage (not shown) is provided to contact the cooling body 1 or is embedded in the cooling body 1. The cooling body 1 is cooled down by the cooling medium passing through the passage. Further, by supplying the gas through the cooling body to the gap between the cooling body and the rear surface of the substrate, the cold of the cooling body can be transferred to cool down the substrate 21.

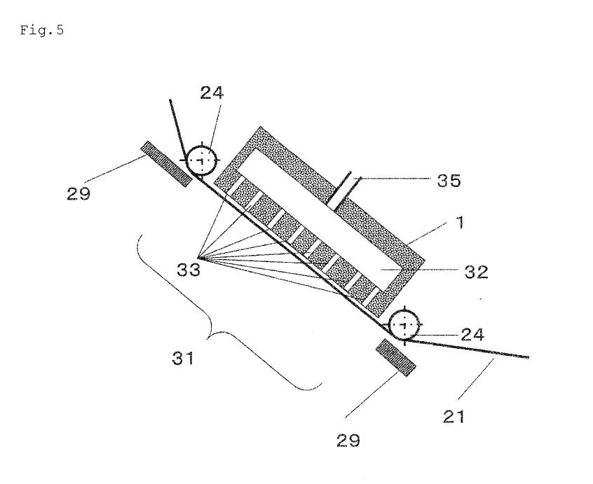

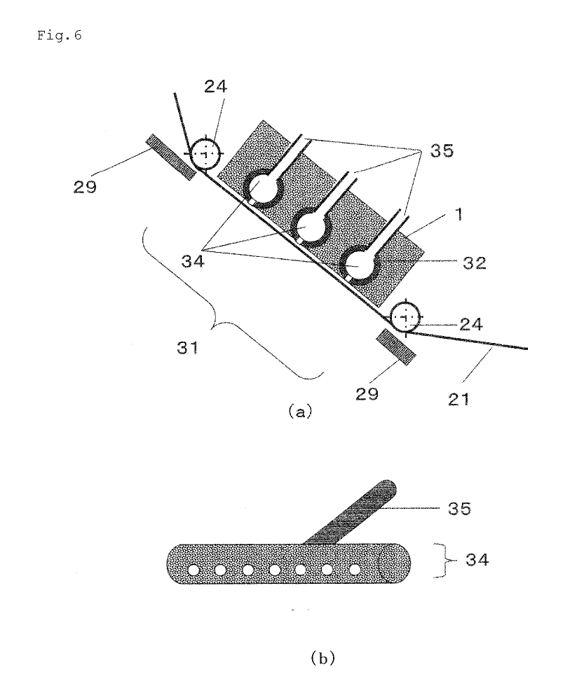

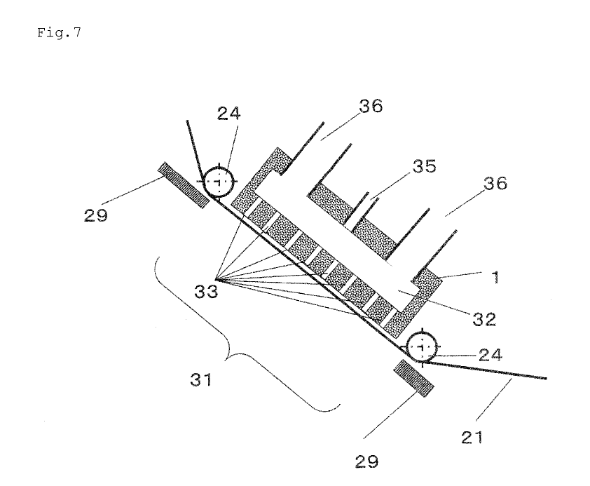

Various methods can be used as a method for introducing the gas to the gap between the cooling body 1 and the substrate 21. Examples are a method for, as shown in FIG. 5, forming a cooling gas introducing port 35 and a manifold 32 in the cooling body 1 and supplying the gas through a plurality of fine holes 33 extending to the surface of the cooling body 1 and a method for, as shown in FIG. 6, embedding a gas nozzle 34 having, for example, a flute-like outlet shape in the cooling body 1 and introducing the gas from the nozzle (FIG. 6(b) shows only the gas nozzle 34). Moreover, as shown in FIG. 7, by adding exhaust ports 36 to the configuration of FIG. 5 and suctioning a part of the gas accumulated between the cooling body 1 and the substrate 21, the flow rate of the gas introduced to between the cooling body and the substrate can be increased, and the temperature increase of the gas can be suppressed.

The foregoing has explained a gas introducing unit configured to cool down the substrate. The film forming apparatus of the present invention may further include a unit configured to introduce a second gas. For example, the material gas introducing tube 30 of FIG. 4 is used as the second gas introducing unit. The material gas introducing tube 30 is, for example, a tubular member having one end located above the evaporation crucible 19 in the vertical direction and the other end connected to a material gas supplying unit (not shown) provided outside the vacuum chamber 22. For example, oxygen, nitrogen, or the like is supplied through the material gas introducing tube 30 to the vapor of the material. With this, a thin film containing as a major component an oxide, nitride, or oxynitride of the material flying from the film forming source 27 is formed on the surface of the substrate 21. Examples of the material gas supplying unit are a gas bomb and a gas generator.

An exhaust unit 37 is provided outside the vacuum chamber 22 and adjusts the inside of the vacuum chamber 22 to a pressure reduced state suitable for the formation of the thin film. For example, the exhaust unit 37 is constituted by various vacuum exhaust systems including as a main pump an oil diffusion pump, a cryopump, a turbo-molecular pump, or the like.

As above, in accordance with a film forming apparatus 20, the substrate 21 supplied from the pull-out roller 23 travels through the feed rollers 24 and is supplied with the vapor flying from the film forming source 27 and, according to need, oxygen, nitrogen, or the like at the opening 31, and thus the thin film is formed on the substrate. The substrate 21 travels through the other feed rollers 24 to be taken up by the take-up roller 26. With this, the substrate 21 on which the thin film is formed is obtained.

Various polymer films, various metal foils, a complex of the polymer film and the metal foil, and elongated substrates of the other materials can be used as the substrate 21. Examples of the polymer film are polyethylene terephthalate, polyethylene naphthalate, polyamide, and polyimide. Examples of the metal foil are aluminum foils, copper foils, nickel foils, titanium foils, and stainless steel foils. The substrate has a width of, for example, 50 to 1,000 mm, and desirably has a thickness of, for example, 3 to 150 μm. In a case where the substrate has a width of less than 50 mm, the bending of a width-direction center portion of the substrate at the time of the gas cooling is not so large, but thin film non-forming regions on both width-direction end portions of the substrate by the application of the present invention become large. However, the present invention is not inapplicable to this case. In a case where the substrate has a thickness of less than 3 μm, the heat capacity of the substrate is extremely small, so that the heat deformation easily occurs. In a case where the substrate has a thickness of more than 150 μm, the bending of the width-direction center portion of the substrate at the time of the gas cooling is not so large. The present invention is not inapplicable to both of these cases. A transfer speed of the substrate differs depending on the type of the thin film to be formed and conditions for the film formation, but is, for example, 0.1 to 500 m/min. A tension applied in the traveling direction of the substrate being transferred is suitably selected depending on the material and thickness of the substrate and process conditions, such as the film formation rate.

### Embodiment 1

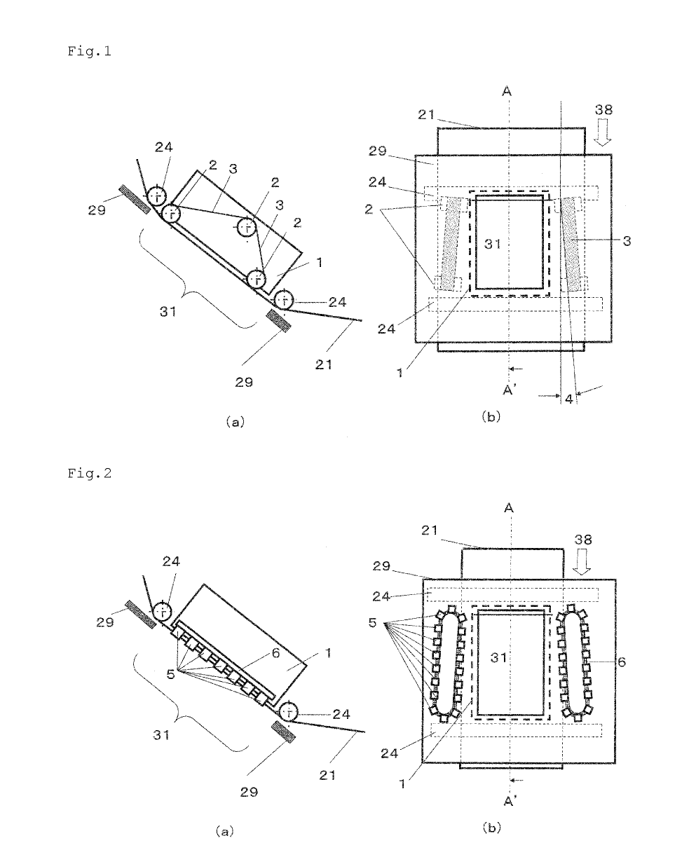

FIG. 1 are diagrams schematically showing the configuration of one example of a substrate cooling mechanism that is a part of Embodiment of the present invention including a width-direction tension applying unit. FIG. 1(a) is a view of a cross section taken along line A-A′ of FIG. 1(b). FIG. 1(b) is a front view of the vicinity of the opening 31 when viewed from the film forming source 27 of FIG. 4.

In the vicinities of both width-direction ends of the substrate in the vicinity of the opening, a pair of endless bands 3 held by a plurality of support rollers 2 revolve along the rear surface of the substrate while contacting the rear surface of the substrate. A surface which faces the film forming source and on which the thin film is formed is defined as a front surface of the substrate whereas a surface opposite to the front surface is defined as the rear surface of the substrate. It is preferable that the endless body 3 have a width of 2 to 50 mm. In a case where the endless body has a width of less than 2 mm, an effect of applying the tension to the substrate in the width direction is small. In a case where the endless body has a width of more than 50 mm, an influence on the thin film forming region is large, and a production efficiency significantly deteriorates.

A travel interval between a pair of endless bodies 3 is set to be constant, or the travel interval is set to become wider from upstream to downstream in the traveling direction of the substrate 21. For example, in a case where the traveling direction of the substrate 21 is regarded as a central axis, the traveling direction of the endless body is set to be away from the central axis. An angle 4 formed by a substrate traveling direction 38 and the traveling direction of the endless body 3 contacting the substrate is from 0 to 45 degrees. Moreover, the angle 4 is desirably from 0 to 10 degrees, more desirably from 0 to 5 degrees. If the angle formed by the substrate traveling direction 38 and the traveling direction of the endless body 3 contacting the substrate increases, it becomes increasingly difficult to smoothly carrying out the traveling of the substrate. If the angle 4 exceeds 45 degrees, especially wrinkles and damages of the substrate tend to occur.

A material of the endless body 3 is not especially limited. The endless body made of a metal, such as stainless steel, nickel, copper, or titanium, excels in heat resistance and durability. In the case of the endless body made of rubber or plastic, a frictional force between the endless body and the substrate is easily obtained, and a width-direction tension is easily applied to the substrate. The endless body made of a composite material, such as the endless body made of the metal material and coated with the rubber material, can also be used.

Moreover, the endless body 3 contacts the substrate 21 and slightly presses the substrate 21 to cause the substrate 21 to deform. If the amount of pressing is too large, harmful effects, such as the deformation, wrinkle, breaking, and the like of the substrate, occur. Therefore, it is desirable that the amount of pressing deformation of the substrate by the endless body be set to 2 mm or less.

By causing the endless body and the substrate to travel while contacting each other, the tension can be applied to the substrate in the width direction. With this, it is possible to prevent the substrate from expanding like a balloon by the introduction of the cooling gas and therefore prevent the gap between the substrate and the cooling body in the vicinity of the width-direction center of the substrate from becoming large. Thus, the interval between the cooling body 1 and the substrate 21 can be controlled uniformly in the substrate width direction.

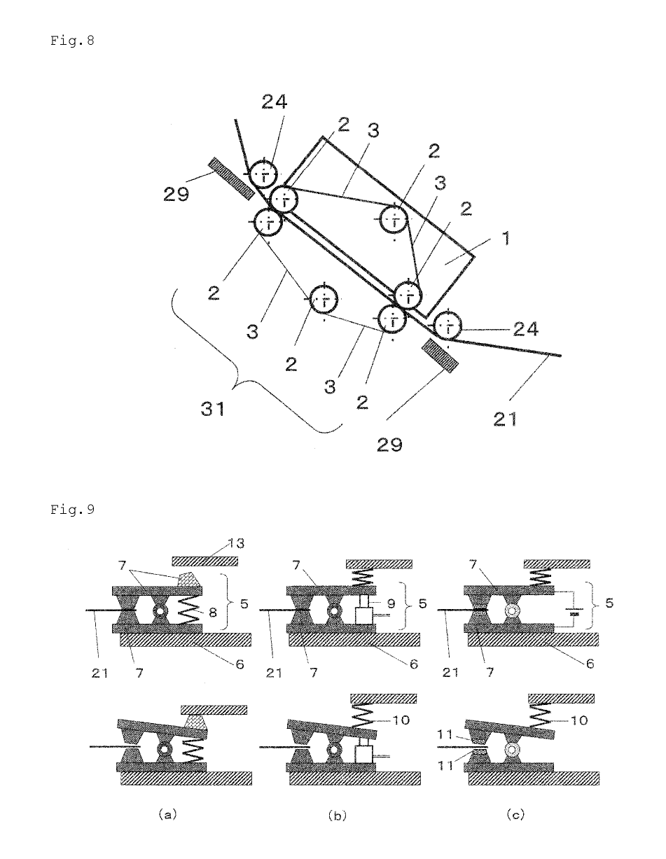

FIG. 1 show an example in which the endless body travels along the rear surface of the substrate. However, in Embodiment 1, the endless body may travel along the front surface of the substrate. Whether the endless body is provided on the front surface side or the rear surface side of the substrate is determined based on process circumstances, such as a space around the thin film forming region and the amount of heat load. Further, as shown in FIG. 8, the endless bodies may sandwich the substrate from both front and rear surfaces of the substrate. In this case, the frictional force between the substrate and the endless body can be significantly improved, so that the tension is easily applied in the substrate width direction. Therefore, the angle formed by the substrate traveling direction and the traveling direction of the endless body contacting the substrate can be made small. This is advantageous in that the smoothness of the traveling of the substrate is maintained. In this case, in order to prevent the substrate from being broken by the high width-direction tension and prevent a sandwiching pressure of the endless bodies to become too high, an adjustment of a pressing force of the endless body by a cushioning mechanism (not shown), such as a spring, is effective.

### Embodiment 2

FIG. 2 are diagrams schematically showing the configuration of another example of the substrate cooling mechanism that is a part of Embodiment of the present invention including the width-direction tension applying unit. FIG. 2(a) is a view of a cross section taken along line A-A′ of FIG. 2(b). FIG. 2(b) is a front view of the vicinity of the opening 31 when viewed from the film forming source 27 of FIG. 4.

The present embodiment is similar to Embodiment 1 except for the vicinity of the opening, so that the same explanations are omitted.

In Embodiment 2, the substrate is sequentially sandwiched by clip mechanisms 5 provided at both width-direction ends of the substrate in the vicinity of the opening. As shown by examples in the schematic diagrams of FIG. 9, the clip mechanism has a sandwiching function of a spring type shown in FIG. 9(a), a pneumatic type shown in FIG. 9(b), an electrostatic type shown in FIG. 9(c), or the like and a releasing function of a gap type, a spring type, or the like. By the sandwiching function acting at the opening 31 and before and after the opening 31 and the releasing function acting in the other region, sandwiching and releasing of the substrate can be controlled. The clip mechanism 5 circulates and is transferred by a clip transfer system 6.

For example, in the case of the spring type of FIG. 9(a), the substrate 21 is sandwiched at the opening 31 and before and after the opening 31 by the force of a compression spring 8 provided between clip pieces 7. After the clip mechanism 5 has passed through the opening 31 by the clip transfer system 6, a gap between the clip piece 7 and a release body 13 provided in advance gradually becomes small, and the substrate 21 is released from the clip mechanism 5 by the contact between the clip piece 7 and the release body 13. In the case of the pneumatic type of FIG. 9(b), the substrate 21 is sandwiched at the opening 31 and before and after the opening 31 by the force of a pneumatic cylinder 9 connected to between the clip pieces 7. After the clip mechanism 5 has passed through the opening 31 by the clip transfer system 6, air pressure is reduced, the clip piece 7 is pulled back by a release spring 10 provided in advance, and the substrate is released from the clip mechanism 5. In the case of the electrostatic type of FIG. 9(c), the substrate 21 is sandwiched at the opening 31 and before and after the opening 31 by an electrostatic force generated by a voltage applied to between the clip pieces 7 each having a dielectric layer 11 on a clip surface. After the clip mechanism 5 has passed through the opening 31 by the clip transfer system 6, the voltage is reduced, the clip piece 7 is pulled back by the release spring 10 provided in advance, and the substrate is released from the clip mechanism 5. FIG. 9 show specific examples of the sandwiching function and releasing function of the clip mechanism. However, various other types of sandwiching function and releasing function may be used. The present invention is not limited to the specific examples of FIG. 9.

A travel interval between a pair of clip mechanisms 5 provided on both width-direction ends of the substrate is set to be constant, or the travel interval is set to become wider from upstream to downstream in the traveling direction of the substrate 21. Moreover, a travel interval between a pair of clip transfer systems 6 provided on both width-direction ends of the substrate is set to be constant, or the travel interval is set to become wider from upstream to downstream in the traveling direction of the substrate 21. The clip transfer system 6 is, for example, a revolving chain mechanism. One end of the clip mechanism 5 is, for example, fixed to the clip transfer mechanism 6. By transferring the substrate 21 while clipping both width-direction ends of the substrate 21, the tension can be applied to the substrate 21 in the width direction of the substrate. With this, it is possible to prevent the substrate from expanding like a balloon by the introduction of the cooling gas and therefore prevent the gap between the substrate and the cooling body in the vicinity of the width-direction center of the substrate from becoming large. Thus, the interval between the cooling body 1 and the substrate 21 can be uniformized in the substrate width direction. Since the clip mechanism 5 moves in the substrate traveling direction 38 while increasing an interval between clips at both width-direction ends of the substrate, the tension can be further strongly applied to the substrate in the substrate width direction. By adjusting a contact area and a sandwiching pressure when the clips sandwich the substrate and an interval between the clip pieces on both sides which interval changes in accordance with the movement of the clips, the tension in the substrate width-direction can be adjusted. Moreover, by arbitrarily changing a travel distance of the interval between the clips when the substrate passes through the opening 31, the tension in the substrate width direction can be finely adjusted in accordance with the progress of the film formation.

### Embodiment 3

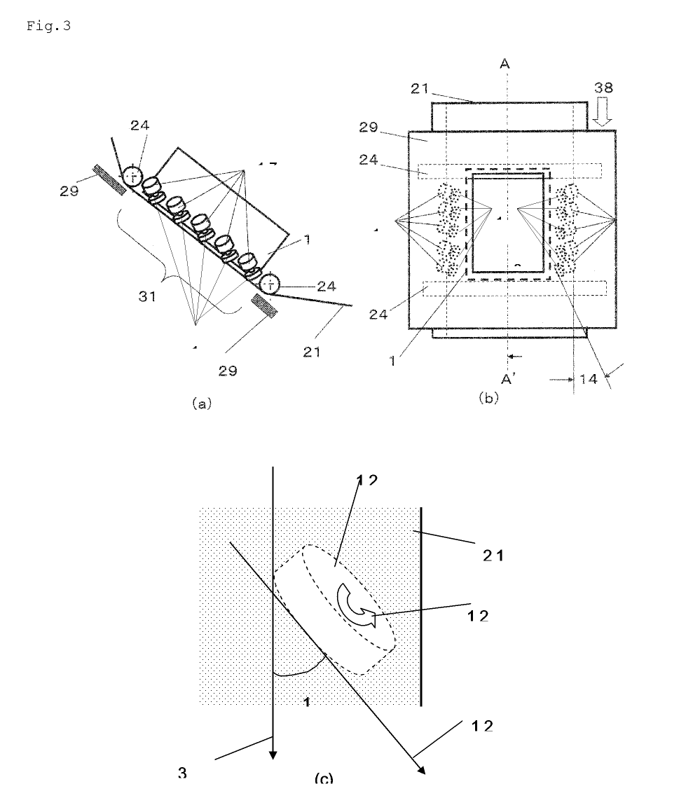

FIG. 3 are diagrams schematically showing the configuration of another example of the substrate cooling mechanism that is a part of Embodiment of the present invention including the width-direction tension applying unit. FIG. 3(a) is a view of a cross section taken along line A-A′ of FIG. 3(b). FIG. 3(b) is a front view of the vicinity of the opening 31 when viewed from the film forming source 27 of FIG. 4. FIG. 3(c) is a partially enlarged view of one rotary sliding body located on the right side in FIG. 3(b). The shielding plate 29 is not shown in FIG. 3(c).

The present embodiment is similar to Embodiment 1 except for the vicinity of the opening, so that the same explanations are omitted.

In Embodiment 3, at the opening 31, the tension is applied to the substrate in the width direction of the substrate by rotary sliding bodies 12 provided in the vicinities of both width-direction ends of the substrate 21. The material of a portion of the rotary sliding body which portion contacts the substrate may be a metal. However, it is desirable that the material of the portion be rubber or plastic in order to obtain the frictional force. It is desirable that a peripheral speed of the rotary sliding body at a position where the rotary sliding body contacts the substrate be 0.5 to 10 times a traveling speed of the substrate. In a case where the peripheral speed is less than 0.5 time the traveling speed of the substrate, braking with respect to the substrate traveling becomes strong, and this tends to cause meandering or wrinkle of the substrate. In a case where the peripheral speed exceeds 10 times the traveling speed of the substrate, breaking of the substrate or abrasion of the substrate by sliding becomes significant, and this tends to cause troubles in a long-time operation. It is further desirable that the peripheral speed of the rotary sliding body at the position where the rotary sliding body contacts the substrate be 1 to 3 times a movement speed of the substrate. The rotary sliding body 12 receives a rotational force from a rotation source 17 via a rotating shaft. As the rotation source 17, a small motor or a secondary rotating body to which a rotation driving force is transferred from a motor or the like via a gear or a chain can be used.

The tension applied to the substrate in the width direction of the substrate can be adjusted by adjusting an angle formed by a rotational direction 12a of the rotary sliding body 12 and the traveling direction 38 of the substrate 21. Specifically, it is desirable that at a position where the rotary sliding body 12 contacts the substrate 21, an angle 14 formed by a tangential movement direction 12b of the rotary sliding body 12 and the substrate traveling direction 38 exceed 0 degree and be equal to or less than 80 degrees toward a substrate end portion direction. It is further desirable that the angle 14 exceed 0 degree and be equal to or less than 45 degrees. In a case where the angle with respect to the traveling direction 38 of the substrate 21 is 0 degree or less, the tension cannot be strongly applied to the substrate in the width direction of the substrate. In a case where the angle exceeds 80 degrees, the braking with respect to the substrate traveling becomes strong, and this causes meandering and wrinkle of the substrate.

The rotary sliding body 12 contacts the substrate and slightly presses the substrate to cause the substrate to deform. If the amount of pressing is too large, harmful effects, such as the deformation, wrinkle, breaking, and the like of the substrate 21, occur. Therefore, it is desirable that the amount of pressing deformation of the substrate 21 by the rotary sliding body 12 be set to 2 mm or less.

FIG. 3 show an example in which the rotary sliding body rotates along the rear surface of the substrate. However, the rotary sliding body may travel along the front surface of the substrate. Whether the rotary sliding body is provided on the front surface side or the rear surface side of the substrate is determined based on process circumstances, such as a space around the thin film forming region and the amount of heat load. Further, the rotary sliding bodies may contact both front and rear surfaces of the substrate. In this case, the frictional force between the substrate and the rotary sliding body can be significantly improved, so that the tension is easily applied in the substrate width direction. Therefore, the angle formed by the substrate traveling direction and the traveling direction of the rotary sliding body contacting the substrate can be made small. This is advantageous in that the meandering and wrinkle of the substrate is prevented, and the smoothness of the traveling of the substrate is maintained. In this case, in order to prevent the substrate from being broken by the high width-direction tension and prevent the pressing force of the rotary sliding bodies to become too high, an adjustment of the pressing force by a cushioning mechanism (not shown), such as a spring, is effective.

### Embodiment 4

The film forming apparatus of the present embodiment includes an endless band which adsorbs to the rear surface of the substrate in a part of the thin film forming region when viewed in the substrate width direction and travels together with the substrate. The configuration of the film forming apparatus is schematically shown in FIGS. 1 and 4.

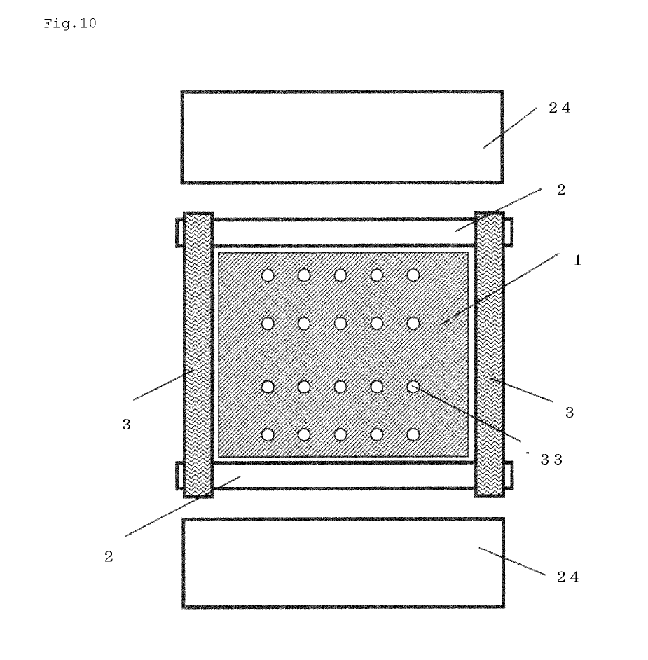

An endless band 3 having an adsorbing ability in the present embodiment is held and driven by a plurality of support rollers 2 while contacting the substrate 21. Next, a positional relation between the endless band 3 having the adsorbing ability and the cooling body 1 will be explained using FIG. 10. FIG. 10 is a diagram showing the vicinity of the cooling body 1 when viewed from the film forming source 27. In order to clearly show the position of the endless band 3, the substrate 21 is not shown in FIG. 10. The endless band 3 and the cooling body 1 are provided between a plurality of feed rollers 24 configured to linearly transfer the substrate 21. Although FIG. 1 shows that the travel interval between a pair of endless bodies 3 increases from upstream to downstream in the traveling direction of the substrate 21, FIG. 10 shows that the travel interval between a pair of endless bodies 3 is constant. It is preferable that in order to prevent the cooling gas from leaking to the vacuum chamber, the pair of endless bands 3 be provided in the vicinities of both width-direction ends of the substrate as shown in FIG. 10, and the cooling gas be introduced to between the pair of endless bands 3. However, the present invention is not limited to this, and the endless band 3 may be provided anywhere on the rear surface of the substrate. For example, a center portion of the substrate deforms most significantly. From this point of view, in a case where the endless band is also provided in the vicinity of a width-direction center of the substrate and adsorbs to the substrate, a cooling effect improves.

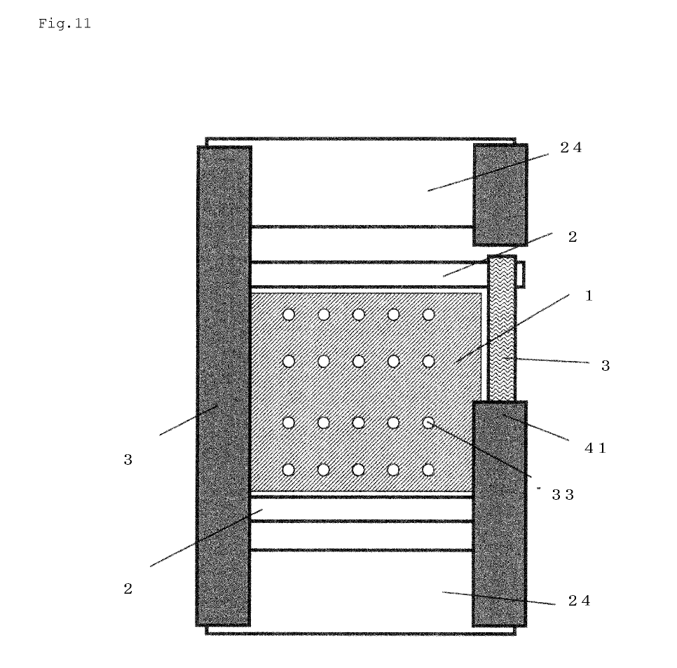

Moreover, the cooling performance can be more stably maintained by providing a shielding plate 41 between the endless band 3 and the film forming source 27 as shown in FIG. 11. In the vacuum deposition or the sputtering, extremely large splash particles are rarely generated in addition to deposition particles generated by the normal film formation and may collide with the substrate. In the case of using the thin foil-like substrate, the surface of the endless band 3 provided as an adsorbing unit on the rear surface of the substrate may be damaged since the splash particles may have energy to break through the substrate. Since the shielding plate 41 can prevent the endless band 3 from being damaged even if the splash particles fly, the adsorbing ability can be stably maintained. In FIG. 11, a part of the shielding plate 41 is not shown in order to clearly show the positional relation between the endless band 3 and the shielding plate 41.

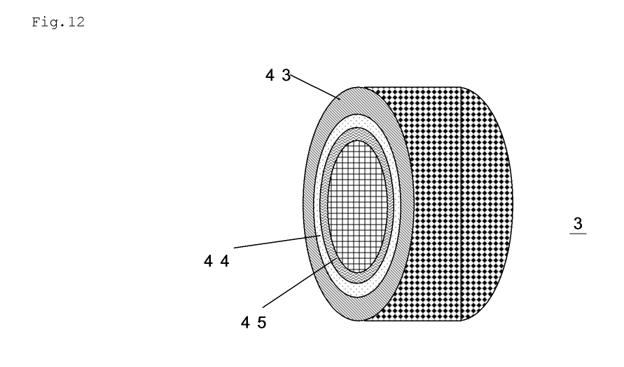

As the endless band 3 having the adsorbing ability, an electrostatic adsorbing belt can be used. As shown in FIG. 12 for example, the electrostatic adsorbing belt includes at least an insulating layer 43 and an electrically-conductive layer 44 in this order from an outer side contacting the substrate 21. According to need, the electrostatic adsorbing belt may include a base material 45 on an inner side of the electrically-conductive layer 44 in order to secure the strength of the endless band. The electrostatic adsorbing belt has a mechanism configured to give a potential difference between the electrically-conductive layer 44 and the substrate 21. During the thin film formation, the potential difference is given between the electrically-conductive layer 44 and the substrate 21. Regarding the giving of the potential difference, as long as there is the potential difference between the electrically-conductive layer and the substrate, one of the electrically-conductive layer and the substrate may have a ground potential, or each of both the electrically-conductive layer and the substrate may have a positive or negative non-ground potential.

It is desirable that in order to increase a contact area between the substrate 21 and the insulating layer 43, a resin having flexibility be used for the insulating layer 43. Specifically, silicon rubber, fluorocarbon rubber, natural rubber, oil synthetic rubber, and the like can be used. Moreover, an endless belt made of a metal, such as SUS304, can be used as the electrically-conductive layer 44. In addition, electrically-conductive paints, electrically-conductive films, metal foils, and the like can be used as the electrically-conductive layer 44. It is desirable that in the case of using a material, such as the electrically-conductive paint, the electrically-conductive film, or the metal foil, having a low mechanical strength, in addition to the insulating layer and the electrically-conductive layer, the base material 45 be provided according to need on the inner side of the electrically-conductive layer 44 in order to secure the strength of the endless band.

Larger the potential difference between the electrostatic adsorbing belt and the substrate is, stronger an electrostatic adsorbing force becomes. However, since the withstand voltage characteristic of the flexible resin used for the insulating layer is limited, it is desirable that the potential difference be substantially from 1 to 3 kV, and the potential difference be about 2 kV.

In a case where the substrate 21 is made from a dielectric material, it is unnecessary to provide the insulating layer 43, and the electrically-conductive layer 44 may be formed to contact the substrate 21. In this case, a voltage is applied to the electrically-conductive layer 44. Here, by giving the potential difference to the electrically-conductive layers 44, the electrically-conductive layers 44 constitute two electrodes and may be used as a bipolar electrostatic adsorbing body.

More conveniently, an endless band formed by a resin material having viscosity may be used as the endless band 3 that is the adsorbing unit. One example of such resin material is silicon rubber. Moreover, according to need, a base material for securing the strength may be provided on an inner side of a layer made of the resin material having the viscosity. With this, the substrate can be adsorbed only by the endless band without specially using a mechanism, such as a power supply. On this account, by simplifying the apparatus, stable operations can be carried out.

### Embodiment 5

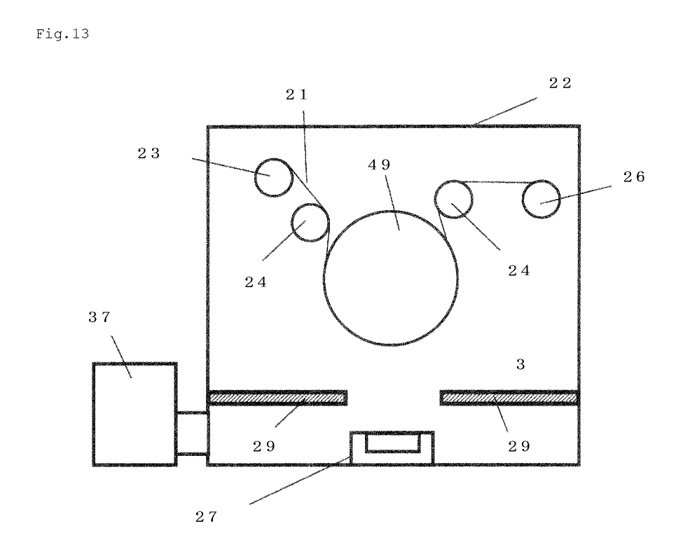

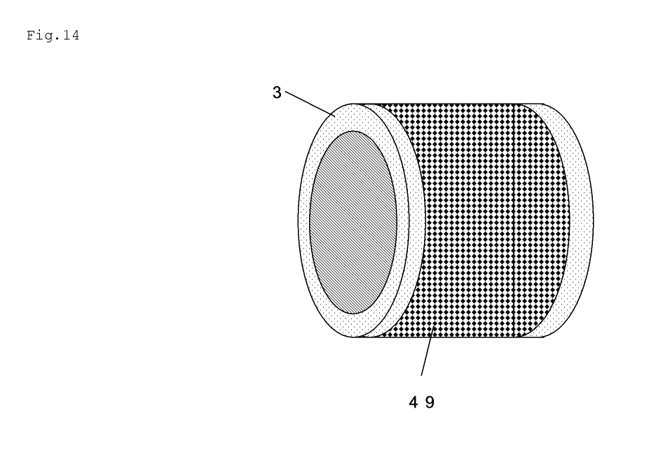

FIG. 13 schematically shows one example of the configuration of the entire film forming apparatus including the endless band configured to, at the thin film forming region, transfer the substrate along a cylindrical can while causing the substrate to be curved, and adsorb to the rear surface of the substrate.

The vacuum chamber 22 is maintained in a pressure reduced state by the exhaust unit 37. The film forming source 27, the pull-out roller 23, a cylindrical cooling can 49, the endless band 3 that is the substrate adsorbing unit, and the take-up roller 26 are provided in the vacuum chamber 22. As shown in FIG. 14, the endless bands 3 are respectively provided on both ends of the cooling can 49 for example. Both ends of the substrate 21 contact and are supported by the endless bands 3. In this case, a gap is formed between the rear surface of the substrate and the surface of the cooling can 49, and a gas is supplied to between the rear surface of the substrate 21 and the cooling can 49 that is the cooling body to cool down the substrate 21. The gas introduction can be realized by, for example, forming a gas introducing port on the surface of the cooling can 49 or using a porous material for the can. The endless bands 3 are respectively provided on both ends of the cooling can 49 and adsorb to the vicinities of both width-direction ends of the substrate 21. This prevents the substrate 21 from bending by the introduction of the cooling gas and being too far away from the can 49. The position of the endless band 3 is not limited to this, and the endless band 3 may adsorb to anywhere on the rear surface of the substrate. For example, a center portion of the substrate deforms most significantly. From this point of view, in a case where the endless band 3 is also provided in the vicinity of the width-direction center of the substrate and adsorbs to the substrate, the cooling effect improves. For example, the endless band 3 can be realized by, for example, providing an adsorbing material, such as silicon rubber, on a part of the can 49.

Again, by providing the shielding plate 41 between the endless band 3 and the film forming source 27, splash particles can be blocked off. Therefore, the endless band 3 can be used without damaging the surface thereof.

As explained above, the film forming apparatus of Embodiments 1 to 5 can prevent the substrate from bending even if the amount of cooling gas introduction is increased, and the pressure at the rear surface of the substrate is increased. Therefore, the substrate can be cooled down uniformly and adequately.

The foregoing has explained an example of the substrate cooling mechanism that is a part of Embodiment of the present invention including a substrate holding unit. However, the present invention is not limited to these embodiments. The other methods can be used as long as they can prevent the substrate from bending in the substrate width direction at the thin film forming region.

As shown in FIG. 4, by forming the opening of the shielding plate at a position where the inclined substrate linearly travels, the film formation of the oblique incidence can be carried out. However, the film formation can be carried out at a position where the substrate horizontally travels. Since the oblique incidence film formation can form the thin film having microspaces by a self-shadowing effect, it is effective for the formation of a high C/N electromagnetic tape, the formation of a battery negative terminal having an excellent cycle characteristic, and the like.

For example, by using a copper foil as the substrate, evaporating silicon from the film forming source, and introducing an oxygen gas according to need, an elongated battery polar plate can be obtained.

Moreover, by carrying out the film formation while using polyethylene terephthalate as the substrate, evaporating cobalt from an evaporation crucible, and introducing the oxygen gas, an elongated electromagnetic tape can be obtained.

As above, the battery polar plate using silicon, the electromagnetic tape, and the like have been explained as specific examples of the application of the present invention. However, the present invention is not limited to these. Needless to say, the present invention is applicable to various devices, such as condensers, various sensors, solar batteries, various optical films, moisture-proof films, and electrically conductive films, which require stable film formation.

### INDUSTRIAL APPLICABILITY

In accordance with the thin film forming apparatus and the thin film forming method of the present invention, the interval between the substrate and the cooling body can be made small and uniform. Therefore, the cooling of the substrate by the gas cooling method can be effectively and uniformly realized.

The present invention is highly effective especially in a case where the amount of gas introduced is increased and the pressure between the substrate and the cooling body is increased in order to improve the performance of the gas cooling. The present invention can carry out the thin film formation realizing both high material use efficiency and high film formation rate.

Therefore, for example, in a case where a high-capacity battery active material layer is formed in a vacuum process, the temperature increase of the substrate can be suppressed. As a result, for example, the reliability and the like of the battery can be improved. Thus, the thin film forming apparatus is useful as an apparatus for use in not only battery applications but also a wide range of thin film formation.

1. A thin film forming apparatus configured to form a thin film on an elongated substrate in vacuum, comprising:
a transfer mechanism configured to transfer the substrate;
a thin film forming unit including a film forming source for forming the thin film on a front surface of the substrate in a thin film forming region while the substrate is being transferred;
a cooling body provided close to a rear surface of the substrate being transferred in the thin film forming region;
a gas introducing unit configured to introduce a gas to between the cooling body and the substrate;
a substrate holding unit configured to hold vicinities of both width-direction ends of the substrate in the thin film forming region while causing the substrate to travel; and
a vacuum container configured to store the transfer mechanism, the thin film forming unit, the cooling body, the gas introducing unit, and the substrate holding unit.

2. The thin film forming apparatus according to claim 1, wherein:
the substrate is linearly transferred in the thin film forming region; and
the substrate holding unit is a width-direction tension applying unit configured to apply tension to the substrate in a width direction of the substrate in the thin film forming region while causing the substrate to travel.

3. The thin film forming apparatus according to claim 2, wherein the width-direction tension applying unit is an endless band revolving along the substrate.

4. The thin film forming apparatus according to claim 3, wherein the endless band is one of a plurality of endless bands provided on vicinities of both width-direction ends of the substrate.

5. The thin film forming apparatus according to claim 4, wherein an interval between the plurality of endless bands increases from upstream to downstream in a travel direction of the substrate.

6. The thin film forming apparatus according to claim 4, wherein the endless bands are provided on both front and rear surfaces of the substrate.

7. The thin film forming apparatus according to claim 2, wherein the width-direction tension applying unit is a clip mechanism configured to sequentially sandwich both width-direction ends of the substrate.

8. The thin film forming apparatus according to claim 2, wherein the width-direction tension applying unit is rotary sliding bodies contacting vicinities of both width-direction ends of the substrate.

9. The thin film forming apparatus according to claim 1, wherein the substrate holding unit is an endless band configured to adsorb to the rear surface of the substrate in a part of the thin film forming region when viewed in a substrate width direction and travel together with the substrate.

10. The thin film forming apparatus according to claim 9, wherein the endless band is one of a plurality of endless bands provided on vicinities of both width-direction ends of the substrate, and the gas is introduced to a space defined by the plurality of endless bands in the width direction of the substrate.

11. The thin film forming apparatus according to claim 9, wherein:
the thin film forming region is formed on the substrate supported by a plurality of rollers and linearly transferred between the plurality of rollers; and
the endless band and the cooling body are provided between the plurality of rollers.

12. The thin film forming apparatus according to claim 9, wherein:
the cooling body is a cylindrical can; and
the thin film forming region is formed on the substrate transferred while the substrate is being curved along the cylindrical can.

13. The thin film forming apparatus according to claim 9, wherein the endless band adsorbs to the rear surface of the substrate by electrostatic adsorption.

14. The thin film forming apparatus according to claim 9, further comprising a shielding unit provided between the endless band and the film forming source.

15. A thin film forming method for forming a thin film on a surface of an elongated substrate in vacuum, comprising the step of: providing a cooling body close to a rear surface of the substrate being transferred in a thin film forming region; and forming the thin film on a front surface of the substrate while introducing a gas to between the cooling body and the substrate to cool down the substrate and while holding, in the thin film forming region, vicinities of both width-direction ends of the substrate being traveled.

16. The thin film forming method according to claim 15, wherein
the vicinities of both width-direction ends of the substrate are held by applying tension to the substrate in the thin film forming region in a width direction of the substrate being traveled.

17. The thin film forming method according to claim 16, wherein the tension is applied to the substrate in the width direction of the substrate by a plurality of endless bands provided on vicinities of both width-direction ends of the substrate.

18. The thin film forming method according to claim 16, wherein the tension is applied to the substrate in the width direction of the substrate by sequentially sandwiching both width-direction ends of the substrate by a clip mechanism.

19. The thin film forming method according to claim 16, wherein the tension is applied to the substrate in the width direction of the substrate by causing rotary sliding bodies to contact vicinities of both width-direction ends of the substrate.

20. The thin film forming method according to claim 15, wherein the vicinities of both width-direction ends of the substrate are held by causing an endless band adsorbing to the rear surface of the substrate in a part of the thin film forming region when viewed in a substrate width direction to travel together with the substrate.
